(19) United States
(12) Patent Application Publication
(10) Pub. No.: US 2009/0096375 A1
(43) Pub. Date: Apr. 16, 2009

(54) Plasma Display Panel and Method for Manufacturing Same

(76) Inventors: Hideki Yamashita, Osaka (JP); Takafumi Okuma, Osaka (JP); Hiroshi Hayata, Osaka (JP); Yoshimasa Takii, Osaka (JP); Hirokazu Nakaue, Osaka (JP); Tadashi Kimura, Hyogo (JP); Masaharu Terauchi, Hyogo (JP)

Correspondence Address: WENDEROTH, LIND & PONACK L.L.P., 2033 K. STREET, NW, SUITE 800, WASHINGTON, DC, 20006, US

(21) Appl. No.: 11/918,002

(22) PCT Filed: Apr. 7, 2006
(86) PCT No.: PCT/JP2006/307445

§ 371 Date: Oct. 5, 2007

(30) Foreign Application Priority Data
Apr. 8, 2005 (JP) 2005-111973

(51) Int. Cl. H01J 17/49; H01J 9/20; C23C 14/34

(52) U.S. Cl. 313/582; 445/58

(57) ABSTRACT

A PDP, which has a plurality of display electrodes formed therein, and is provided with a front plate in which the display electrodes are covered with a first dielectric layer and a protective film and a back plate having a plurality of address electrodes that are formed in a direction orthogonal to the display electrode, and covered with a second dielectric layer (backing dielectric layer, is designed so that the protective film has a structure in which grain-state crystals are aggregated and a grain size of the crystals is large, with a void between adjacent crystals being formed with a small size.

### TECHNICAL FIELD

The present invention relates to a plasma display panel (hereinafter, referred to as PDP) which has become widely applied as a flat-panel-type display apparatus (referred to also as flat panel display) for use in a large-size television as well as in a public display for advertisement, information, and the like, and also concerns a method for manufacturing such a plasma display panel. In particular, the present invention relates to a plasma display panel with a protective film, which is used at a low output and capable of maintaining superior display quality even after long time operations, and a manufacturing method for such a plasma display panel.

### BACKGROUND ART

In recent years, the PDP, used as a large-size flat panel display, in which ultraviolet rays, generated by the discharge of rare gas, excite phosphors to emit light to realize an image/video image display, has been developed to achieve such a large-size product as to have a diagonal length of 1 m or more. The developments of PDPs have been accelerated, and new techniques have been developed one after another, in order to achieve high-performance and low-price products and optimal mass-production systems for use as display apparatuses, such as information processing apparatuses typically represented by computers, or as large-size television receivers and public display monitors.

The PDPs include an AC driving system and a DC driving system, and FIGS. 9A and 9B are views that schematically explain a structure of a PDP of a general AC driving system (hereinafter, a PDP of an AC driving system is referred to as “AC-type PDP”). There are various types of the AC-type PDPs, and FIG. 9A, which shows one example of a type referred to as “surface discharge type”, is a perspective view that depicts one portion of the structure three-dimensionally, and FIG. 9B is a cross-sectional view that shows an AA portion of FIG. 9A in an enlarged manner. The PDP has a structure in which line electrodes and column electrodes are respectively placed on a front glass substrate 101 and a back glass substrate 108 orthogonally so that an intersection between the two line and column electrodes, which forms a pixel, and partition walls 111, located between the two substrates 101 and 108, are allowed to form a discharge space 124.

FIG. 10 is a flow chart of production processes that schematically shows a manufacturing method of a general AC-type PDP. In FIG. 10, the production processes of a general AC-type PDP are mainly classified into a forming process S110 of a front plate, a forming process S120 of a back plate, and an assembling process S130 of these plates. The front plate forming process S110 is composed of a scan electrode/sustain electrode forming process S111 and a dielectric layer forming process S112 and a dielectric protective film forming process (hereinafter, referred to simply as a protective film forming process) S113. Moreover, the back plate forming process S120 is composed of a data electrode forming process S121, a backing dielectric layer forming process S122, a partition wall forming process S123, and a phosphor layer forming process 124, and the assembling process S130 is composed of an adhesion-sealing process S131, an evacuation process S132, a discharge gas sealing process S133, an aging process 134, and a PDP panel completion process S135; thus, a PDP 121 is completed through these processes.

The following description will discuss the structures of the front plate 122 and the back plate 123 of an AC-type PDP of the general surface discharge type, shown in FIGS. 9A and 9B, in association with processes shown in FIG. 10.

In the front plate 122, a plurality of sustain electrodes 103, used for inputting a sustaining signal for discharging, and a plurality of scan electrodes 102, used for inputting a scanning signal for a sequential displaying operation, are formed on the front glass substrate 101, in pairs and in parallel with each other through the scan electrode/sustain electrode forming process S111 shown in FIG. 10; thus, line electrodes that form display electrodes 104 are formed. Next, a transparent dielectric layer 106, used for forming a wall charge derived from discharging, is formed on these display electrodes 104 through the dielectric layer forming process S112. Moreover, a protective film 107 used for protecting the dielectric layer 106 from ion impacts caused by discharging (hereinafter, referred to also as protective film) is formed on the dielectric layer 106 through the protective film forming process S113. Moreover, a black matrix, which forms a shielding layer, is sometimes formed between the paired electrodes constituted by the adjacent sustain electrode 103 and scan electrode 102, if necessary, in order to enhance the contrast of the display surface; however, in FIG. 10, this forming process is omitted.

Next, in the back plate 123, a plurality of address electrodes 110 (referred to also as data electrodes), which form column electrodes used for inputting a plurality of display data signals, are formed on a back glass substrate 108 in directions that respectively intersect the sustain electrodes 103 and the scan electrodes 102 forming the display electrodes 104 of the front plate 122, through the data electrode forming process S121 shown in FIG. 10. Next, a backing dielectric layer 109, used for forming a wall charge derived from discharging, is also formed on these address electrodes 110 through a backing dielectric layer forming process S122, and on this layer, partition walls 111 are further formed in parallel with the address electrodes 110 through a partition wall forming process S123 so that phosphor layers 112R, 112G, and 112B, which respectively emit red, green, and blue light rays, are formed between the partition walls 111 through a phosphor layer forming process S124.

Moreover, the front plate 122 and the back plate 123 are bonded to each other, with their electrode formation faces being made face to face with each other, to form an adhesion sealed panel, by using a sealing material such as flit glass (through adhesion-sealing process S131), and after this has been subjected to a degassing process (evacuating process S132) while being heated, a rare gas, such as He, Ne, or Xe, is filled therein as a discharge gas under a pressure of 400 Torr to 600 Torr (discharge gas sealing process S133), and an aging process in which a driving pulse having a predetermined voltage and waveform is applied to each of the electrodes of the panel to execute a discharging process is carried out (aging process S134); thus, a PDP 121 in which the discharge space 124 is formed is manufactured (PDP panel completing process S135).

In the PDP 121 thus completed, in order to supply electric signals to the scan electrodes 102 and the sustain electrodes 103 as well as to the address electrodes 110 serving as the column electrodes, a circuit board on which driver ICs used for driving are mounted is connected to the electrode terminals of these electrodes, and this is assembled into a box-shaped member together with a control signal circuit and a power supply circuit so that a display apparatus is completed. Voltage pulses having predetermined signals are applied to the display electrodes 104 constituted by the sustain electrodes 103 and the scan electrodes 102, and the address electrodes 110 so that the filled rare gas is excited to discharge ultraviolet rays; thus, the ultraviolet rays allow the respective color phosphor layers 112R, 112G, and 112B, placed between the partition walls 111, to excite visible light rays to emit red, green, and blue light rays so that information formed by color images and the like can be displayed.

In particular, in the forming process S110 of the front plate 122, the sustain electrodes 103, the scan electrodes 102, and the dielectric layer 106 are formed on the front glass substrate 101, and in order to protect the dielectric layer 106 from ion impacts derived from discharging and also to accelerate light emission of the phosphor caused by a secondary electron discharging process, a protective film 107 is formed thereon under predetermined conditions through electron beam evaporation, and magnesium oxide (MgO) is widely used as this protective film 107. The MgO film, formed through electron beam evaporation in this manner, is a fine film with a high crystallizing property, and has a superior sputtering resistant property, as well as a superior characteristic of exerting a high secondary electron discharging coefficient. Moreover, in order to improve the protective performance for protecting the dielectric layer 106 from ion impacts caused by gas discharging and also to achieve discharging with high response by reducing a discharging voltage, improvements in the crystallographical structure and various physical properties of the protective film 107 have been proposed (for example, see Patent Document 1 and Patent Document 2).

Patent Document 1: Japanese Unexamined Patent Publication No. 11-54045

Patent Document 2: Japanese Unexamined Patent Publication No. 2002-75226

### DISCLOSURE OF INVENTION

### Issues to be Solved by the Invention

As described above, with respect to the PDP, there have been strong demands for higher precision and lower power consumption, and developments have been made in high energy discharge gas or increased number of scanning lines. In an attempt to provide a PDP with high precision, the sputtering in the dielectric protective film is accelerated in response to an increase in ion impact energy in the discharge cells in the PDP panel container, resulting in the possibility of a shortened service life of the protective film, with the result that a further improvement in the sputtering resistant property of the protective film is raised as one of the objectives to be achieved. Moreover, in response to an increase in the number of scanning lines in an attempt to provide high precision devices, it is necessary to narrow the pulse width of an address pulse to be applied to the address electrodes so as to carry out a high speed driving operation; however, in a high precision PDP actually manufactured, due to a discharge delay phenomenon in which discharging takes place with a considerable delay from the rise of an applied pulse, the possibility of completing a discharge within an applied pulse width becomes lower, causing a phenomenon such as a failure in writing a cell that is to be lighted on, with the result that a defective lighting of a discharging cell in a PDP tends to occur due to this phenomenon. In order to shorten the period of this discharge delay, a high electron discharging performance is required for the protective film. However, the above-mentioned proposals for improving the crystallographical structure and the various physical properties of the protective film 107 so as to achieve the protective performance for protecting the dielectric layer 106 from ion impacts caused by gas discharging and the discharging having a high response by reducing a discharging voltage have not provided satisfactory performances and characteristics yet.

The present invention has been devised to solve the above-mentioned issues, and its objective is to provide a plasma display panel that is capable of forming a dielectric protective film having a high density, which is applicable to a PDP with high precision, and has a superior sputtering resistant property, and carrying out a high-precision displaying process, and has a long service life, and also to provide a method for manufacturing such a plasma display panel.

### Means for Solving the Issues

In order to achieve the above-mentioned object, the present invention has the following arrangements.

According to a first aspect of the present invention, there is provided a plasma display panel comprising:

a first substrate having a first glass substrate on which a first electrode, a first dielectric layer, and a protective film are formed; and

a second substrate having a second glass substrate on which a second electrode, a second dielectric layer, partition walls, and phosphor layers are formed,

wherein the first substrate and the second substrate are aligned face to face with each other with discharge spaces interposed in between, the protective film has a structure in which grain-state crystals are aggregated, and on a surface of the protective film, an area occupied by voids among the crystals is set in a range greater than 0% and less than 10%, with respect to an area of the protective film.

According to a second aspect of the present invention, there is provided the plasma display panel according to the first aspect, wherein the grain-state crystals of the protective film have a minimum particle size in a range of from 30 nm to 100 nm, inclusive.

According to a third aspect of the present invention, there is provided the plasma display panel according to the first or second aspect, wherein the protective film is formed by at least one kind of material selected from the group consisting of an oxide, fluoride, hydroxide, and carboxide of an alkaline earth metal.

According to a fourth aspect of the present invention, there is provided the plasma display panel according to claim the first or second aspect, wherein the protective film is formed by a compound prepared by mixing at least two kinds of materials selected from the group consisting of an oxide, fluoride, hydroxide, and carboxide of an alkaline earth metal.

According to a fifth aspect of the present invention, there is provided the plasma display panel according to the first or second aspect, wherein the protective film is made from magnesium oxide, and the protective film has a film density of greater than 3.3 g/cm³.

With these arrangements, by setting the porosity of the protective film to be formed on the front plate of a PDP in a range of from 0% or more to less than 10%, the etching rate is improved, and the sputtering resistant property is also enhanced to manufacture a dielectric protective film having a high density so that a PDP display using a PDP that is expected to provide a long service life and applicable to a high precision device can be achieved

Moreover, by allowing the grain-state crystals of the protective film to have a minimum particle size in a range of from 30 nm to 100 nm, the etching rate is further improved, and since a PDP, manufactured by using such a front plate, makes it possible to shorten the discharge delay time (a period of time from application of a voltage across the scan electrode and the address electrode to an occurrence of discharging during an address period), the sputtering resistant property is further enhanced to ensure a longer service life, and the discharging characteristics are also improved so that a PDP display using a PDP that is superior in display quality is achieved.

Moreover, in order to achieve the above-mentioned object, in accordance with a sixth aspect of the present invention, there is provided a method of manufacturing a plasma display panel having a structure in which a first substrate having a first glass substrate on which a first electrode, a first dielectric layer, and a protective film are formed and a second substrate having a second glass substrate on which a second electrode, a second dielectric layer, partition walls, and phosphor layers are formed are aligned face to face with each other with discharge spaces interposed in between, the method comprising:

carrying the first substrate having the first dielectric layer formed thereon into a vacuum container;

supplying H₂O gas into the vacuum container together with a sputter gas; and

forming the protective film on the first substrate, while a flow rate of the H₂O gas is being controlled by monitoring a gas partial pressure of the H₂ gas in the vacuum container.

According to a seventh aspect of the present invention, there is provided the method of manufacturing a plasma display panel according to the sixth aspect, wherein a gas pressure of the sputter gas to be supplied into the vacuum container is set to 0.5 Pa, and the first substrate is heated to a predetermined temperature in a range of from 250° C. to 350° C., and then the protective film is formed by using a sputtering method, with a pressure ratio of the H₂O gas being set in a range of from 10⁻⁴ to 10⁻¹, inclusive with respect to a total pressure inside the vacuum container.

By using the manufacturing method of a PDP having these processes, the etching rate of the protective film to be formed on the front plate is improved, and since a PDP, manufactured by using such a front plate, makes it possible to shorten the discharge delay time, the sputtering resistant property is further enhanced to ensure a longer service life, and the discharging characteristics are also improved so that a PDP display using a PDP that is superior in display quality is achieved.

### EFFECTS OF THE INVENTION

In accordance with the present invention, the protective film has a structure in which grain-state crystals are aggregated, and on the surface of the protective film, an area occupied by voids among the crystals is set in a range of from 0% or more to less than 10%, with respect to the area of the protective film; therefore, it becomes possible to obtain a protective film that is superior in the sputtering resistant property. Consequently, great effects are achieved such that a PDP that is superior in image quality with high precision, and has a long service life can be achieved.

Moreover, by allowing the grain-state crystals of the protective film to have a minimum particle size in a range of from 30 nm to 100 nm, inclusive, it becomes possible to provide a protective film that can shorten the discharge delay time, provide a good electron-discharging characteristic, and achieve a superior sputtering resistant property. Consequently, great effects are achieved such that a PDP that is superior in image quality with high precision, and has a long service life can be achieved.

### BRIEF DESCRIPTION OF DRAWINGS

These and other aspects and features of the present invention will become clear from the following description taken in conjunction with the preferred embodiments thereof with reference to the accompanying drawings, in which:

FIG. 1A is an exploded perspective view that shows an enlarged structure of one portion of an AC-type PDP in accordance with an embodiment of the present invention;

FIG. 1B is a cross-sectional view that shows an AA portion of FIG. 1A in an enlarged manner;

FIG. 1C is a flow chart of manufacturing processes that schematically explains a manufacturing method of the AC-type PDP in the embodiment of the present invention;

FIG. 2 is a schematic constituent view that shows an apparatus used for forming a protective film on a front plate of the PDP of the embodiment of the present invention;

FIG. 3 is a graph that shows a relationship between the porosity and the discharge delay time of an MgO film of each of total six kinds of samples including samples for comparative references and samples of actual examples of the embodiment of the present invention;

FIG. 4 is a graph that indicates a relationship between the minimum particle size and the discharge delay time of the MgO film of each of the above-mentioned samples;

FIG. 5 is a graph that indicates a relationship between the film density and the discharge delay time of the MgO film of each of the above-mentioned samples;

FIG. 6 is a graph that indicates a relationship between the porosity and the etching rate of the MgO film of each of the above-mentioned samples;

FIG. 7 is a graph that indicates a relationship between the minimum particle size and the etching rate of the MgO film of each of the above-mentioned samples;

FIG. 8 is a graph that indicates a relationship between the film density and the etching rate of the MgO film of each of the above-mentioned samples;

FIG. 9A is a view that schematically explains a structure of a general AC-type PDP;

FIG. 9B is a view that schematically explains a structure of the general AC-type PDP; and

FIG. 10 is a flow chart of manufacturing processes, which schematically explains a manufacturing method of a general AC-type PDP.

### BEST MODE FOR CARRYING OUT THE INVENTION

Before the description of the present invention proceeds, it is to be noted that like parts are designated by like reference numerals throughout the accompanying drawings.

Referring to Figures, the following description will discuss a PDP and its manufacturing method in accordance with embodiments of the present invention.

### EMBODIMENTS

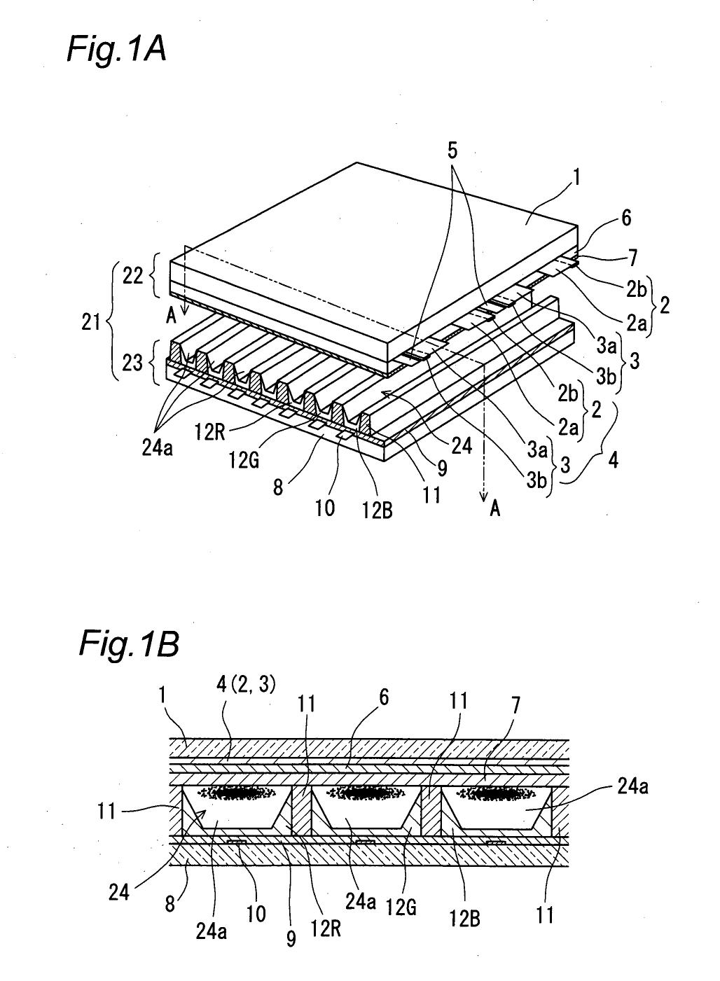

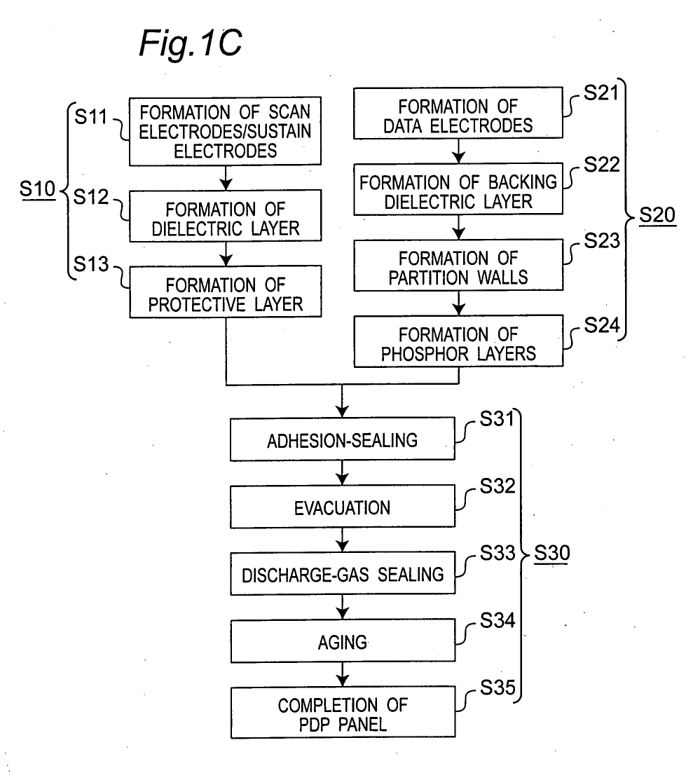

Referring to FIGS. 1A to 8, the following description will discuss one embodiment of the present invention.

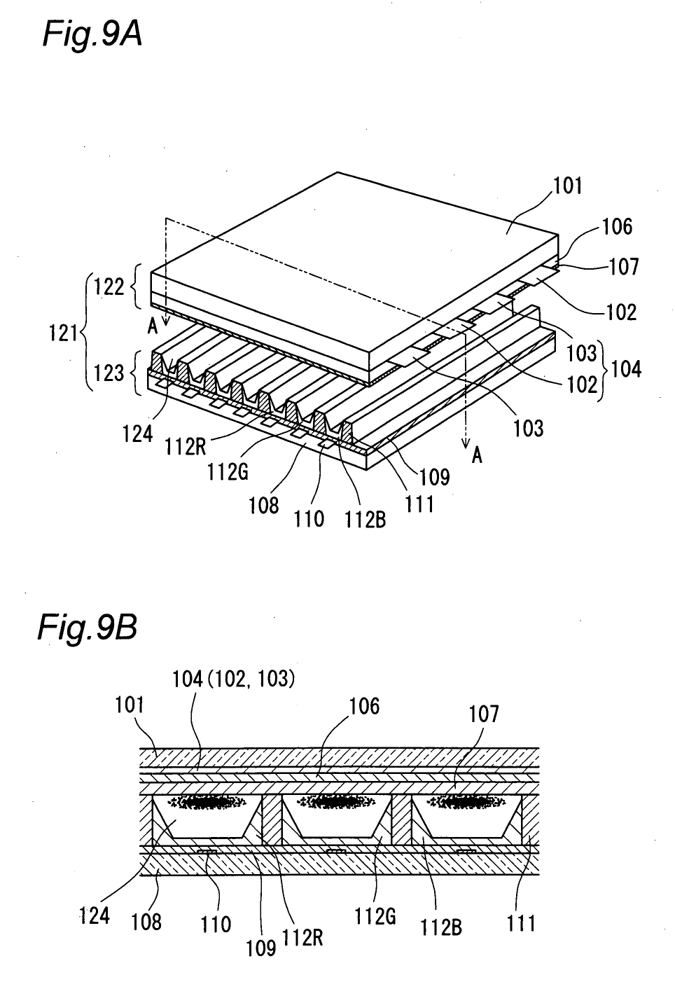

FIG. 1A is an exploded perspective view that shows an enlarged structure of one portion of an AC-type PDP in accordance with the embodiment of the present invention, FIG. 1B is a cross-sectional view that shows an AA portion of FIG. 1A in an enlarged manner, and FIG. 1C is a flow chart of manufacturing processes that schematically explains a manufacturing method of the AC-type PDP in the embodiment of the present invention. Here, the structure of the general AC-type PDP has already been explained by reference to FIGS. 9A and 9B as the prior art, and although the AC-type PDP in accordance with the embodiment of the present invention has a structure similar to the structure in which line electrodes and column electrodes are arranged orthogonally on a front glass substrate 1 and a back glass substrate 8 made of glass, respectively so that an intersection between two line and column electrodes forming a pixel and partition walls 11 between the two substrates 1 and 8 are allowed to form each discharge space 24, this structure is again explained based upon FIGS. 1A and 1B.

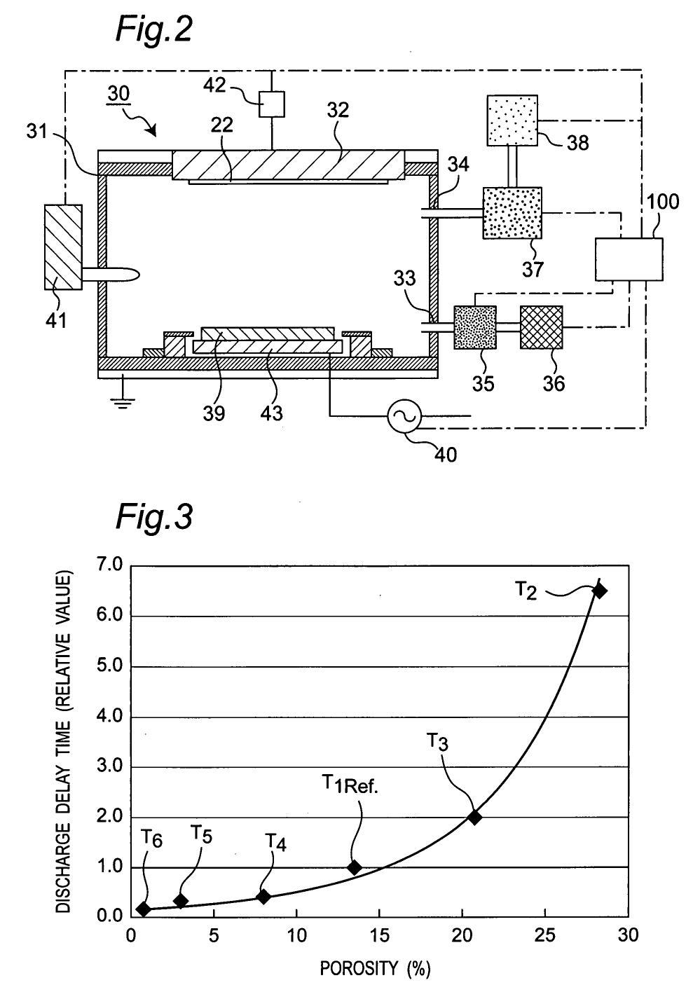

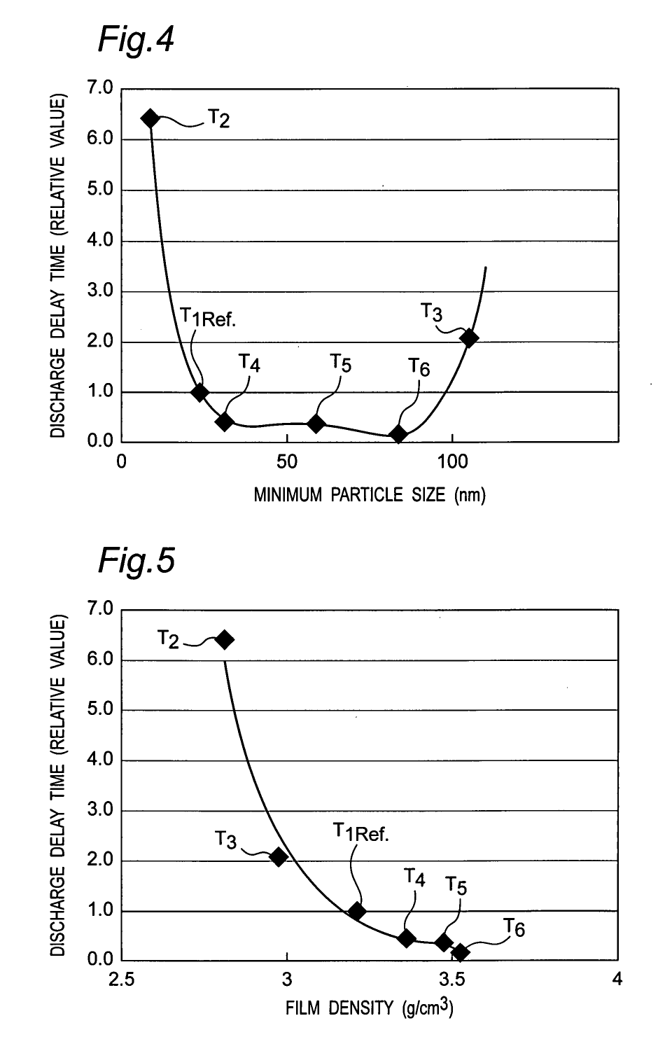

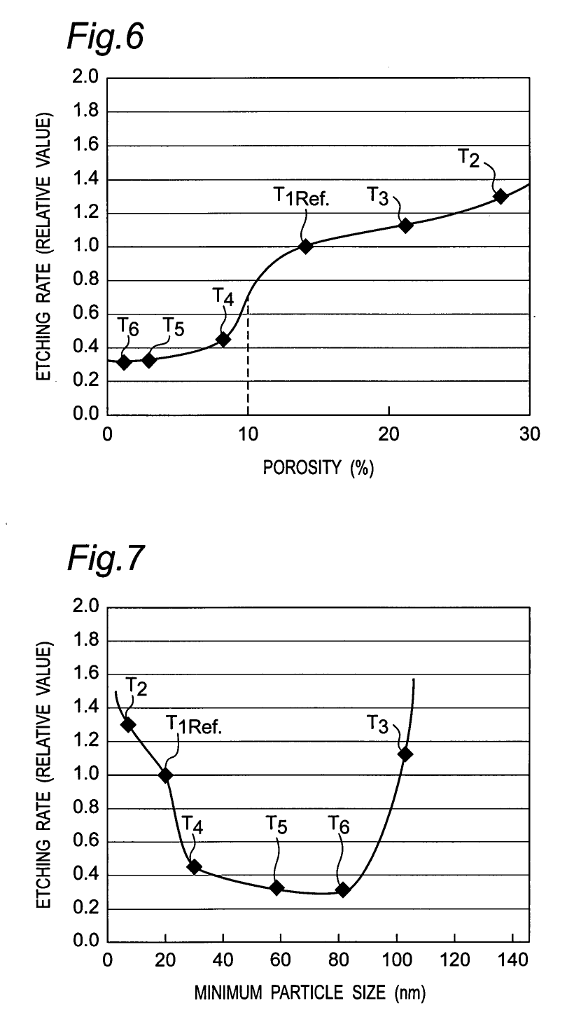

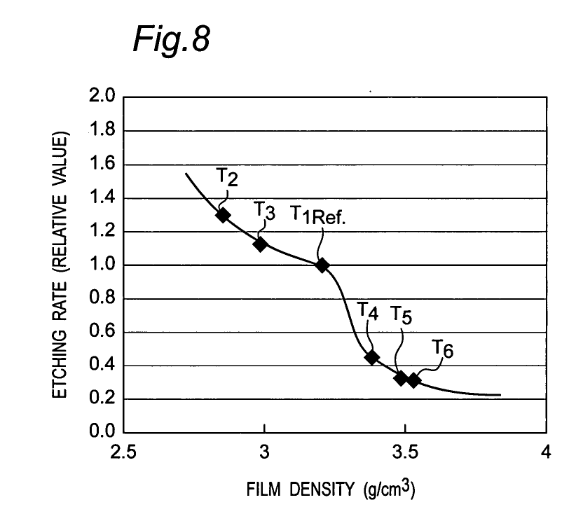

Here, FIG. 2 is a schematic constituent view that shows an film-forming apparatus used for forming a protective film 7 on a front face plate of the PDP of the embodiment of the present invention, FIG. 3 is a graph that shows a relationship between the porosity and the discharge delay time of an MgO film of each of total six kinds of samples including samples for comparative references and samples of actual examples of the embodiment of the present invention, FIG. 4 is a graph that indicates a relationship between the minimum particle size and the discharge delay time of the MgO film of each of the above-mentioned six kinds of samples, FIG. 5 is a graph that indicates a relationship between the film density and the discharge delay time of the MgO film of each of the above-mentioned six kinds of samples, FIG. 6 is a graph that indicates a relationship between the porosity and the etching rate of the MgO film of each of the above-mentioned six kinds of samples, FIG. 7 is a graph that indicates a relationship between the minimum particle size and the etching rate of the MgO film of each of the above-mentioned six kinds of samples, and FIG. 8 is a graph that indicates a relationship between the film density and the etching rate of the MgO film of each of the above-mentioned six kinds of samples.

In each of FIGS. 1A and 1B, on the front plate 22, a plurality of pairs of display electrodes 4, each pair consisting of a scan electrode 2 used for sequential displaying and a sustain electrode 3 to which a discharge sustaining signal is inputted that are aligned face to face with each other as well as in parallel with each other with a discharge gap, are formed on a transparent front glass substrate 1 in a stripe pattern (corresponding to so-called line electrodes). These scan electrode 2 and sustain electrode 3 are constituted by transparent electrodes 2a and 3a formed by ITO (Indium-Tin Oxide), SnO₂, or the like, and auxiliary electrodes (referred to also as bus electrodes) 2b and 3b that are electrically connected to these transparent electrodes 2a and 3a, and made from, for example, thick films of silver or the like, or aluminum (Al) thin films, or laminated thin films of chrome (Cr)-copper (Cu)-chrome (Cr). Moreover, in order to enhance the contrast of the display surface, a shielding layer 5 (referred to also as BS film) serving as a black matrix may be formed between the paired electrodes forming the sustain electrode 3 and the scan electrode 2 which are adjacent, if necessary. Furthermore, on the front glass substrate 1, a transparent dielectric layer 6, which is made of low-melting-point glass and used for forming a wall charge derived from a discharge, is formed on the group of a plurality of pairs of display electrodes 4 in a manner so as to cover the group of the plurality of pairs of display electrodes 4, and on this dielectric layer 6, a protective film 7, which is made from magnesium oxide (MgO) and used for protecting the dielectric layer 6 from ion impacts caused by a discharge, is formed; thus, these constituent elements form the front plate 22. Here, the auxiliary electrodes 2b and 3b of the display electrodes 4 may have a two-layer structure in which, in order to enhance the contrast, after the transparent electrodes 2a and 3a have been formed on the front glass substrate 1, a dark color conductive layer is preliminarily formed, and a conductive layer is then formed thereon by using a predetermined conductive material.

Moreover, on the back glass substrate 8 that is aligned face to face with the front glass substrate 1, a plurality of address electrodes 10 (corresponding to so-called column electrodes) (referred to also as data electrodes) to which a display data signal is inputted are formed in a stripe pattern in a direction orthogonal to the display electrodes 4 on the front glass substrate 1, while being covered with a backing dielectric layer 9. The backing dielectric layer 9, used for forming a wall charge derived from a discharge, is formed on the data electrodes 10, and on the backing dielectric layer 9 on the data electrodes 10, a plurality of partition walls 11 are placed in parallel with the data electrodes 10 in a stripe pattern so that phosphor materials, which emit light rays of three colors, R (red), G (green), and B (blue), are applied onto the side faces between the partition walls 11 as well as onto the surface of the backing dielectric layer 9 to form phosphor layers 12R, 12G, and 12B respectively; thus, the back plate 23 is formed.

Here, the front plate 22 and the back plate 23 having the above-mentioned structures are aligned face to face with each other with a fine discharge space 24 (or a plurality of fine discharge cells) located in between so that the display electrodes 4 corresponding to the line electrodes constituted by the scan electrode 2 and the sustain electrode 3 and the data electrodes 10 corresponding to the column electrodes are made orthogonal to each other, and with the front plate 22 and the back plate 23 being aligned face to face with each other, the peripheral portion thereof is sealed, and after having been high-vacuum-evacuated by a pressure of, for example, a degree of vacuum of about 1×10⁻⁴ Pa, a mixed gas composed of rare gas components such as He, Ne, and Xe is injected and filled in the discharge spaces 24 as a discharge gas under a predetermined pressure (for example, a pressure of 400 Torr to 600 Torr). For example, as the discharge gas, a mixed gas of neon (Ne) of 90 volume %-xenon (Xe) of 10 volume % is filled therein under a pressure of 66.5 kPa (500 Torr). Moreover, the discharge space 24 is divided by the partition walls 11 into a plurality of thin, long sections so that a plurality of discharge cells 24a in which intersections between the display electrodes 4 and the data electrodes 10 are located are formed. Thus, as described earlier, the blue, green, and red phosphor layers 12B, 12G, and 12R are sequentially placed in the discharge cells 24a to constitute a PDP 21. Here, by applying voltage pulses of predetermined signals to the sustain electrode 3 and the scan electrode 2 as well as to the data electrode 10, a rare gas component in the discharge gas filled in each of the discharge cells 24a is excited to emit a vacuum ultraviolet ray with a short wavelength (147 nm) so that the phosphor layers 12B, 12G, and 12R placed on the backing dielectric layer 9 and the partition walls 11 are allowed to excite visible light rays by the ultraviolet ray to emit blue, green, and red color rays; thus, information (for example, information formed by color images and the like) can be displayed on the PDP 21. Here, upon driving such a PDP 21, since the same driving waveform is applied to all the sustain electrodes 3 in desired synchronized timing, the sustain electrodes 3 placed adjacent with each other are mutually connected on the front glass substrate 1.

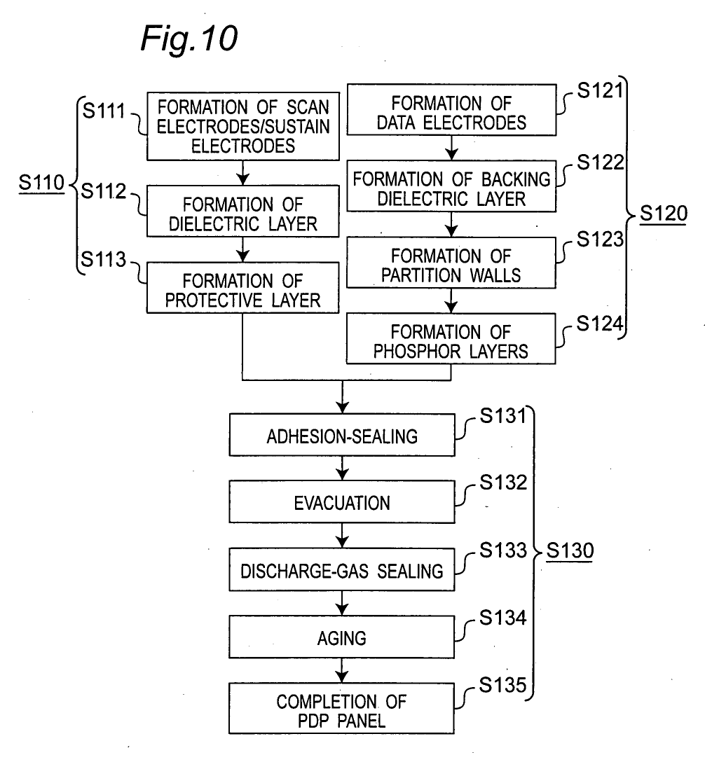

Next, the following description will briefly discuss a manufacturing method of the PDP 21 as a whole, and as shown in FIG. 1C, the PDP 21 in the embodiment of the present invention is manufactured in accordance with a sequence of processes similar to the sequence as already explained in the prior art section by using the flow chart of the manufacturing processes of FIG. 10. In FIG. 1C, the manufacturing processes of the AC-type PDP 21 of the embodiment are mainly classified into a forming process S10 of the front plate, a forming process S20 of the back plate, and an assembling process S30 of these parts. The forming process S10 of the front plate is constituted by a scan electrode/sustain electrode forming process S11, a dielectric layer forming process S12, and a dielectric protective film forming process S13 (hereinafter, also referred to simply as “protective-film forming process”). On the other hand, the back plate forming process S20 is constituted by a data electrode forming process S21, a backing dielectric layer forming process S22, a partition wall forming process S23, and a phosphor layer forming process S24. The assembling process S30 is constituted by respective processes including an adhesion-sealing process S31, an evacuating process S32, a discharge gas sealing process S33, an aging process S34, and a PDP panel completing process S35; thus, the above-mentioned PDP 21 is completed through these processes.

More specifically, first, after the transparent electrodes 2a and 3a respectively forming the scan electrode 2 and the sustain electrode 3 of the display electrodes 4 have been formed on the front glass substrate 1 (scan electrode/sustain electrode forming process S11), the auxiliary electrodes 2b and 3b, which respectively form the scan electrode 2 and the sustain electrode 3 together with the transparent electrodes 2a and 3a, and a shielding layer 5 are formed thereon. In this case, in order to enhance the contrast, each of the auxiliary electrodes 2b and 3b may be formed to have a two-layer structure in which a dark color conductive layer is formed on each of the transparent electrodes 2a and 3a, with a conductive layer being formed thereon by using a predetermined conductive material. These forming methods will be described later.

Next, after glass paste has been applied onto the front glass substrate 1 by using, for example, a screen printing method in a manner so as to cover the transparent electrodes 2a and 3a, the auxiliary electrodes 2b and 3b, and the shielding layer 5, this is fired (calcined) at a predetermined temperature for a predetermined period of time (for example, at 560° C. for 20 minutes) so that the dielectric layer 6 having a predetermined thickness (for example, about 20 μm) is formed (dielectric layer forming process S12). As the glass paste used upon forming the dielectric layer 6, for example, a mixture of PbO (70 wt %), B₂O₃ (15 wt %), SiO₂ (10 wt %), Al₂O₃ (5 wt %), and an organic binder (for example, prepared by dissolving ethyl cellulose (10%) in α-terpineol) is used. Here, the organic binder is a material formed by dissolving resin in an organic solvent, and, besides ethyl cellulose, an acrylic resin is used as the resin, and butyl carbitol or the like may be used as the organic solvent. Moreover, a dispersant (for example, glycerin trioleate) may be mixed in such an organic binder. Moreover, instead of screen-printing by using paste, a molded film-state dielectric precursor may be laminated and fired to form the dielectric layer 6.

Next, the protective film 7 is formed on the dielectric layer 6 (protective film forming process S13). The protective film 7 is made from, for example, magnesium oxide (referred to also as MgO), and formed by using a film-forming process, for example, a vacuum vapor deposition method so as to have a predetermined thickness (for example, about 0.5 μm). By using these methods, the scan electrodes 2, sustain electrodes 3, shielding layer 5, dielectric layer 6, and protective film 7, which are structural objects, are formed on the front glass substrate 1 so that a front plate 22 is manufactured. Here, with respect to the film-forming method and conditions of the protective film 7, detailed explanations will be given later.

Moreover, the data electrodes 10 are formed on the back glass substrate 8 in a stripe pattern (data electrode forming process S21). More specifically, a film is formed on the back glass substrate 8 by using a material for the data electrodes 10, for example, a photosensitive Ag paste, for example, through a screen printing method, and this is then patterned by using, for example, a photolithographic method, and fired so that the target electrodes 10 are formed.

Next, a backing dielectric layer 9 is formed in a manner so as to cover the data electrodes 10 thus formed (backing dielectric layer forming process S22). The backing dielectric layer 9 is formed through the following processes: for example, after, for example, a glass paste containing a lead-based glass material has been applied through, for example, a screen printing process, the resulting film is fired at a predetermined temperature for a predetermined period of time (for example, at 560° C. for 20 minutes) so as to have a predetermined layer thickness (for example, about 20 μm). Moreover, instead of screen-printing glass paste, for example, a molded film-state backing dielectric layer precursor may be laminated and fired to form the target layer.

Next, the partition walls 11 are formed, for example, in a stripe pattern (partition wall forming process S23). The partition walls 11 are formed by film-forming a photosensitive paste mainly composed of an aggregate such as Al₂O₃ and flit glass through a screen printing method, a dye coat method, or the like, and by patterning through, for example, a photolithographic method and firing the resulting film. Alternatively, for example, a paste containing a lead-based glass material is repeatedly applied with predetermined pitches through, for example, a screen printing method, and the resulting film is then fired to provide the partition walls. Here, in the case of an HD-TV (High Definition-TV) of 32 inches to 50 inches, for example, the dimension of the gap between the partition walls 11 is set in a range of from about 130 μm to about 240 μm.

Moreover, phosphor layers 12R, 12G, and 12B, which emit red (R), green (G), and blue (B) light rays, are formed in grooves (discharge cells) 24a between the partition walls 11 (phosphor layer forming process S24). In this process, paste-state phosphor inks each of which is composed of phosphor particles of each of the colors and an organic binder are applied thereto, and these are fired at a temperature of, for example, 400° C. to 590° C. so that the organic binder is burned and eliminated to form phosphor layers 12R, 12G, and 12B composed of the respective phosphor particles that are mutually bonded and joined. By using these methods, the data electrodes 10, backing dielectric layer 9, partition walls 11, phosphor layers 12R, 12G, and 12B, which are structural objects, are formed on the back glass substrate 8 so that the back plate 23 is manufactured.

Successively, for example, low-melting-point flit glass is applied to the peripheral portion of the back plate 23 having the back glass substrate 8 bearing the structural objects such as the phosphor layers 12R, 12G, and 12B formed thereon, and dried thereon, and this back plate 23 and the front plate 22 having the front glass substrate 1 bearing the protective film 7 and the like formed thereon are aligned face to face with each other, and subjected to a heating process so that the front plate 22 and the back plate 23 are adhesion-sealed by the low-melting-point flit glass (adhesion-sealing process S31).

Thereafter, the discharge space 24 between the front plate 22 and the back plate 23 is high-vacuum-evacuated (for example, 1.1×10⁻⁴ Pa) while being heated so that a degassing process is carried out (evacuating process S32).

Next, a rare gas, such as He, Ne, or Xe, is included into the discharge space 24 and filled therein as a discharge gas under a pressure of 400 Torr to 600 Torr (discharge gas sealing process S33).

Moreover, an aging process in which a driving pulse having a predetermined voltage and waveform is applied to each of the electrodes of the panel to execute a discharging process is carried out (aging process S34).

As a result, a PDP 21 in which the discharge space 24 is formed is manufactured (PDP panel completing process S35).

The following description will discuss the protective film 7 to be formed on the dielectric layer 6 of the front plate 22 of the PDP 21 in accordance with the embodiment of the present invention together with its forming method, in detail.

Normally, as the method for film-forming the protective film 7 on the dielectric layer 6 of the front plate 22, an electron beam evaporation method or a sputtering method is used. Here, a method in which the protective film 7 is film-formed by using a film-forming device through the sputtering method as shown in FIG. 2 is explained. In FIG. 2, a front glass substrate 1 for use in the front plate 22 is transported, and mounted on a mounting base 32 inside a vacuum container 31 of a film-forming device 30. The mounting base 32 can heat the front plate 22 so as to raise the temperature thereof by using a heating device 42, such as a resistance heater. An exhaust hole 33 is formed in the vacuum container 31, and the pressure inside the vacuum container 31 is maintained at a predetermined pressure by a pressure adjusting device 36, while the inside of the vacuum container 31 is being evacuated by an exhaust device 35. Here, in a separate position from the exhaust hole 33, a gas inlet 34 is formed in the vacuum container 31, and from a gas supply device 38 used for supplying a sputter gas mainly composed of a rare gas such as Ar, the sputter gas is introduced into the vacuum container 31 through a gas introducing device 37, passing further through the gas inlet 34, so that the inside of the vacuum container 31 is maintained at a predetermined pressure. Moreover, a quadrupol mass spectrometer (Q-mass) 41 is attached to the vacuum container 31 so that the gas types and the respective partial pressures inside the vacuum container 31 can be monitored and measured. The front plate 22 is heated to a predetermined temperature by the heating device 42, and when predetermined high-frequency power is applied to a target 39 by a high-frequency power supply 40 connected to a target holding base 43 that holds and secures the target 39 used for sputtering, a discharge in the rare gas such as Ar takes place near the target 39 inside the vacuum container 31 so that plasma ions, generated by the discharge, sputter the MgO target 39 to form an MgO protective film 7 on the front glass substrate 1 placed face to face with the target 39. In this case, the predetermined high-frequency power is preferably set to, for example, 2 kW or more from the viewpoint of mass productivity. Here, reference numeral 100 in FIG. 2 represents a control device for controlling the film-forming operations of the film-forming device 30, and data of the gas types and the respective partial pressures inside the vacuum container 31, monitored and measured by the quadrupol mass spectrometer 41, are inputted by the control device 100 so that the respective operations of the heating device 42, exhaust device 35, pressure adjusting device 36, gas supply device 38, gas introducing device 37, and high-frequency power supply 40 are controlled.

Before actually film-forming the MgO protective film 7, experiments were carried out so as to find various conditions required for the film forming. Here, a plurality of front glass substrates 1 and 101, made of soda lime glass, to be used for manufacturing the front plates 22 and 122 were prepared, and subjected to the experiments. Moreover, the film-forming method of the MgO protective film 107 in which the electron beam evaporation method is used is a conventional method generally used, and the detailed description thereof is omitted.

After display electrodes 4 and 104 as well as dielectric layers 6 and 106 had been preliminarily formed successively on the respective front glass substrates 1 and 101, protective films 7 and 107, made of six types of MgO, were film-formed thereon by using the film-forming device 30 or a conventional film-forming device, not shown, used for the electron beam evaporation method, through the sputtering method or the electron beam evaporation method. Among the protective films 7 and 107 made of the six types of MgO, the protective film 107 made from one type of MgO, that was, sample T_{1Ref.}, was film-formed through the electron beam evaporation method, which was a conventional method generally used, as a film used for comparison and reference. This was defined as a comparative reference sample T_{1Ref.} Moreover, with respect to the protective films 7 made of the other five types of MgO, that was, samples, T₂, T₃, T₄, T₅, and T₆, since it had been known from the experimental results that various properties of the MgO film were greatly influenced by H₂O gas in the ambient gas at the time of the film-forming process, the MgO films were formed under different conditions, upon supplying a mixed gas, prepared by mixing Ar gas and H₂O gas in the gas supply device 38 of the film-forming device 30 shown in FIG. 2, to the vacuum container 31 through the gas inlet 34 via the gas introducing device 37, by changing the substrate temperature of the front glass substrate 1 and the flow rate of the H₂O gas. The conditions at the time of the film-forming process are shown below:

Pressure of sputter gas inside the vacuum container 31=0.5 Pa

Ar gas flow rate=100 standard cc·m (hereinafter, referred to simply as sccm),

H₂O gas flow rate=0 sccm or more to 30 sccm or less,

Substrate temperature of front glass substrate 1: 250° C. to 350° C., and

Thickness of MgO film thus formed: 600 nm to 700 nm.

Among these conditions, H₂O gas flow rate and the substrate temperature were successively increased so that samples of five kinds of MgO films were prepared. The five kinds of samples were denoted by T₂, T₃, T₄, T₅, and T₆.

With respect to the H₂O gas flow rate of the above-mentioned conditions, in the case where the quadrupol mass spectrometer 41, installed in the film-forming device 30 or a conventional film-forming device used for the electron beam evaporation method, not shown, is used, the sensitivity for an ion current of H₂ the mass number of which is 2 becomes higher than that of H₂O the mass number of which is 18 so that by monitoring the H₂ partial pressure, the H₂O gas flow rate can be desirably controlled with high precision. Therefore, for example, in the film-forming device 30 of the above-mentioned embodiment, during the film-forming process of the MgO protective film 7, the H₂ partial pressure in the formed film was monitored by the control device 100 by using the quadrupol mass spectrometer 41 installed in the vacuum container 31 of the film-forming device 30, and the gas introducing device 37 and the gas supply device 38 were respectively controlled by the control device 100 so that the H₂O gas flow rate was controlled. In the conventional film-forming device, the experimenter controlled the H₂O gas flow rate. Here, the H₂O gas flow rate is clearly described as being set in a range of from 0 sccm or more to 30 sccm or less; however, since the H₂O gas flow rate is a parameter that is not dependant on the film-forming device, the pressure ratio of H₂O to the total pressure of the vacuum container 31 of the film-forming device is desirably set in a range of from 10⁻⁴ to 10⁻¹.

Values of the H₂ partial pressures of the respective samples (T_{1Ref.}, T₂, T₃, T₄, T₅, and T₆) are shown in the following Table 1.

TABLE 1

| Sample No. | T_{1Ref.} | T₂ | T₃ | T₄ | T₅ | T₆ |
|---|---|---|---|---|---|---|
| H₂ partial pressure | 0.020 | 0.005 | 0.011 | 0.062 | 0.150 | 0.247 |

Here, the sputter film-forming method is used as the film-forming method for samples, T₂, T₃, T₄, T₅, and T₆, relating to the embodiment of the present invention, and the electron beam evaporation method, which has been conventionally used in many cases, is used as the film-forming method for the comparative reference sample T_{1Ref.}; however, the present invention is not intended to be limited by these methods, and another film-forming method, such as a CVD method or a sol-gel method, may be used to form the MgO protective film 7, as long as the method is capable of controlling the H₂ partial pressure. Moreover, the characteristics of the resulting MgO protective film 7 are not determined only by the H₂ partial pressure, and are dependent on other parameters, which will be described later, and in this case, the value of the H₂ partial pressure is taken as a typical parameter and shown in Table 1 so that the characteristics of the MgO protective films 107 and 7 are classified with respect to various values of the H₂ partial pressure.

With respect to these samples prepared for forming the front plates 122 and 22, the density, minimum particle size, and porosity of each of the resulting MgO protective films 107 and 7 were found. The density is found through calculations based upon the area and the film thickness of the formed film, and an increase in the weight caused by the film formation of each of the front plates 122 and 22. Since the resulting MgO protective films 107 and 7 are formed into a film state as an aggregated body of pillar-shaped crystals that have grown virtually perpendicularly on the surfaces of the dielectric layers 106 and 6, the minimum particle sizes and the porosities are obtained by observing the enlarged surfaces of the resulting MgO protective films 107 and 7. As the porosity, assuming a value obtained by subtracting the area occupied by the pillar-shaped crystals from the area of the formed film as an area of voids, this area of voids is divided by the area of the formed film to obtain the value. Here, in the MgO film of the PDP 21 in the above-mentioned embodiment of the present invention, it is essential to obtain not the average particle size, but the minimum particle size, as will be described later.

Here, with respect to the etching rate that forms a scale for the sputtering resistant property, the evaluation was made in the following manner. Each of front plates 22 formed by using the respective six types of samples (T_{1Ref.}, T₂, T₃, T₄, T₅, and T₆) including the comparative reference sample T_{1Ref.} was mounted on the mounting base 32 inside the vacuum container 31 of a film-forming device 30 that was the same as the film-forming device 30 used for film-forming the MgO protective film 7, and a bias voltage was applied thereto inside the vacuum container 31 by a high-frequency power supply 40 so that, by exposing the respective front plates 22 to an Ar plasma, the MgO films were dry-etched; thus, the amounts of etching per unit time were calculated to find each etching rate. The etching rates are used for evaluating the amounts of the MgO films etched by ions in the discharging process of the PDP 21 in a simulated manner, and serves as an important scale indicating the performance characteristics of the MgO film.

Moreover, after each of the front plates 122 and 22 of the respective six types of samples T_{1Ref.}, T₂, T₃, T₄, T₅, and T₆ including the comparative reference sample had been heated at a predetermined temperature in a heating furnace (not shown), each plate was combined with the corresponding back plates 123 and 23 experimentally produced in a separated manner, adhesion-sealed, and then subjected to the aforementioned manufacturing processes, such as the evacuating, discharge gas filling, and aging processes, so that a PDP was completed. Each of the PDPs completed by using the front plates of the respective six types of samples T_{1Ref.}, T₂, T₃, T₄, T₅, and T₆ was mounted on a PDP panel characteristic inspection base (not shown), and the discharge delay time was measured. Since the discharge delay time of the PDP is shortened when an MgO film having a high electron discharging performance is used, the discharge delay time also forms an essential parameter indicating the performance characteristics of the MgO film.

With respect to the samples of the six types of MgO films thus formed, the respective characteristic values of the porosity, the density, the minimum particle size, and etching rate as well as the discharge delay time are collectively shown in the following Table 2. In Table 2, the characteristic values of the discharge delay time and etching rate of each of the samples T₂, T₃, T₄, T₅, and T₆ are indicated as relative values based upon the value of sample T_{1Ref.} by which the MgO film was formed through the electron beam evaporation method that is a conventional generally-used method (in other words, with the value of sample T_{1Ref.} being defined as 1.00).

TABLE 2

| Sample No. | T_{1Ref.} | T₂ | T₃ | T₄ | T₅ | T₆ |
|---|---|---|---|---|---|---|
| Porosity (%) | 13 | 28 | 20 | 8 | 3 | 1 |
| Density (g/cm³) | 3.22 | 2.82 | 2.98 | 3.37 | 3.48 | 3.53 |
| Minimum particle size (nm) | 22 | 10 | 104 | 30 | 58 | 82 |
| Discharge delay time | 1.00 | 6.47 | 2.06 | 0.41 | 0.29 | 0.12 |
| (relative ratio) | | | | | | |
| Etching rate | 1.00 | 1.30 | 1.12 | 0.45 | 0.34 | 0.33 |
| (relative ratio) | | | | | | |

Based upon the data shown in Table 2, the data of the respective characteristics were plotted on graphs (see FIGS. 3 to 8), and the MgO film of each of the experimentally produced samples was evaluated based upon the correlation thereof.

FIG. 3 is a graph that shows a relationship between the porosity (%) and the discharge delay time (relative value) of the MgO film of each of the six kinds of samples. FIG. 3 indicates that the MgO film formed by each of the samples, T₄, T₅, and T₆, has a greatly reduced discharge delay time in comparison with the MgO film of sample T_{1Ref.} that is film-formed through the electron beam evaporation method, which is a conventional generally-used method. This indicates that the discharge delay time is quickly reduced as the porosity reduces. Here, since the porosity of the sample T_{1Ref.} is 13%, the porosity is set to less than 13% in order to improve the discharge delay time in comparison with the sample T_{1Ref.} that is formed through the conventional electron beam evaporation method. Therefore, by forming an MgO film having a porosity of less than 13%, it becomes possible to produce an MgO film having a high electron-discharging performance, which is applicable to high-definition apparatuses.

FIG. 4 is a graph that indicates a relationship between the minimum particle size (nm) and the discharge delay time (relative value) of an MgO film of each of the six types of samples. As shown in FIG. 4, the discharge delay time is quickly reduced when the size of the minimum particle size becomes 30 nm or more, and is then again increased when it exceeds 100 nm. For this reason, it is found that the discharge delay time is reduced when the minimum particle size in the grain size distribution is within a range of from 30 nm to 100 nm, inclusive, that is, the electron-discharging performance of the MgO film is improved within this range.

Moreover, FIG. 5 is a graph that indicates a relationship between the film density (g/cm³) and the discharge delay time (relative value) of the MgO film of each of the six types of samples. As shown in FIG. 5, as the film density of the MgO film increases, the discharge delay time is quickly reduced, and when the film density is greater than 3.3 g/cm³ this tendency becomes conspicuous.

As for the reason that an MgO film (MgO film of each of the samples, T₄, T₅, and T₆) having a higher electron-discharging performance is obtained in comparison with the sample T_{1Ref.} that is formed through the conventional electron beam evaporation method, the influences of the reduction in porosity, the size of the minimum particle size of the MgO film, and the high density are taken into consideration. The following description will discuss and explain the influences of the porosity, the minimum particle size, and the film density of the MgO film given to the discharge delay time.

The discharge system of the PDP is a so-called “dielectric barrier discharge” in which a discharging process is conducted through a dielectric material. With respect to the dielectric barrier discharge, it has been well known that the discharging state varies upon a change in conditions of the dielectric material, such as dielectric constant (for example, see page 512 of “Flat Panel Display Unabridged Dictionary”, edited by Tatsuo Uchita and Hiraki Uchiike, Kogyo Chosakai Publishing, Inc., 2001). Based upon this fact, the following explanations are given with respect to the influences of the porosity, the minimum particle size, and the film density of the MgO film given to the discharge delay time.

In other words, when many voids are present on the surface of an MgO film, various discharging paths are formed due to irregularities near the surface. When the porosity becomes greater due to these, the discharge delay time becomes longer. In contrast, in the case when a high density MgO film is prepared with less voids on the surface, since the discharging paths are comparatively aligned, deviations in discharging become smaller, thereby shortening the discharge delay time. Moreover, with respect to the minimum particle size, in the case where those small particles having a particle size of less than 30 nm are present, since the particle size, in particular, near the surface of the MgO film becomes irregular to cause unnecessary discharging paths, the discharge delay time becomes longer. Moreover, in the case where the minimum particle size becomes greater to exceed 100 nm, the number of gaps on the surface of the MgO film increases to cause an increase in the porosity, with the result that the discharge delay time becomes longer. In contrast, when the porosity in the MgO film increases to cause a reduction in the film density, the specific surface area of the MgO film increases to cause adsorption of moisture and impurities onto the surface; this also forms one of the reasons that make the discharge delay time longer.

Therefore, as explained above, in the case where the porosity of an MgO film is made greater than 0% and less than 13% on the surface of the protective film (for example, in a portion from the uppermost surface to a depth of 50 nm), the minimum particle size in the grain size distribution (for example, diameter of a circle corresponding to the surface area of the portion from the uppermost surface to a depth of 50 nm) is set in a range of from 30 nm to 100 nm, inclusive and the film density is greater than 3.3 g/cm³ in the case of using MgO as the film material, the discharge delay time characteristic can be greatly improved as indicated by the samples, T₄, T₅, and T₆, in comparison with the MgO film of the sample T_{1Ref.} through the conventional electron beam evaporation method. Here, the upper limit value of the film density is preferably set to 3.58 g/cm³ in practical use, in the case of, for example, the C-axis orientation MgO film.

Next, with respect to the etching rate shown in Table 1, data were plotted on a graph in the same manner as described for the discharge delay time, and based upon the correlation, each of MgO films of respective samples experimentally produced was evaluated. FIG. 6 is a graph that indicates a relationship between the porosity (%) and the etching rate (relative value) of an MgO film of each of the six types of samples. FIG. 6 shows that in the MgO films formed on the samples T₄, T₅, and T₆, the etching rate is greatly reduced in comparison with the MgO film of the sample T_{1Ref.} film-formed through the conventional generally-used electron beam evaporation method. This indicates that as the porosity reduces, the etching rate quickly reduces. In other words, more specifically, it is found that there is a flexion point at a porosity of 10%. Consequently, it is the porosity of less than 10% that improves the etching rate characteristic in comparison with the sample T_{1Ref.} formed through the conventional electron beam evaporation method. Therefore, by forming MgO having a porosity of less than 10%, it becomes possible to manufacture an MgO film (dielectric protective film) with high density, which is superior in the sputtering resistant property.

Moreover, FIG. 7 is a graph that indicates a relationship between the minimum particle size (nm) and the etching rate (relative value) of the MgO film of each of the six types of samples. As shown in FIG. 7, when the minimum particle size is 30 nm or more, the etching rate quickly reduces, and when the minimum particle size exceeds 100 nm, the etching rate again increases. This indicates that the etching rate is reduced when the minimum particle size in the particle size distribution is in a range of from 30 nm to 100 nm, inclusive; in other words, the MgO film gets hardly sputtered against ion impacts in a discharging process.

FIG. 8 is a graph that indicates a relationship between the film density (g/cm³) and the etching rate (relative value) of the MgO film of each of the six types of samples. As shown in FIG. 8, as the film density of the MgO film increases, the etching rate quickly reduces, and when the film density is greater than 3.3 g/cm³, this tendency becomes conspicuous.

These results indicate that it is possible to manufacture an MgO film (dielectric protective film) with high density that is superior in the sputtering resistant property and consequently to achieve a PDP that is capable of providing a high-definition display, and has a long service life. As the factors that achieved is an MgO film having a higher sputtering resistant property in comparison with the sample T_{1Ref.} formed by the conventional electron beam evaporation method, it is considered that the influences from the reduction in the porosity, the minimum particle size of the MgO film, and the high density thereof are listed. The following description will discuss and explain the influences of the porosity of the MgO film, the minimum particle size, and the film density given to the etching rate (that is, the sputtering resistant property).

Normally, the bulk MgO in a single crystal forms the firmest structural body, and provides the highest sputtering resistant property; in contrast, in the case of a thin-film MgO, it has been well known that the MgO film after a film forming process is composed of fine crystals, each having a pillar-shaped structure, that are aggregated into a grain state. Taking this into consideration, the fact that the porosity of the MgO film, the minimum particle size, and the film density give influences to the etching rate (that is, the sputtering resistant property) is explained as follows:

In other words, an MgO film, formed into a thin film, has a pillar-shaped structure in which grain-state crystals are aggregated, and gaps are formed between grain boundaries of the grain-state crystals, with the result that the film easily crumbles and is also easily etched upon collision with ions. Therefore, by making the particle size greater, with voids being made smaller, to provide a high density, the surface of the MgO film is formed into a structure close to a single crystal structure so that the etching rate is reduced and the sputtering resistant property is improved. Here, it is considered that, when the minimum particle size becomes too large (for example, exceeding 100 nm), the gaps in the surface of the MgO film, that is, the area of void portions, also increase, making the film easily etched. In contrast, when the minimum particle size is small (for example, less than 30 nm), deviations in the particle size distribution become greater, making the grain-state crystals having a pillar-shaped structure uneven, with the result that the film is easily etched, and the corresponding portions are selectively etched to easily crumble. In any case, it is preferable to form the MgO film into a pillar-shaped structure.

As explained above, it is confirmed that in the case where the porosity of an MgO film is set in a range of from 0% or more to less than 10%, the minimum particle size in the particle size distribution is set in a range of from 30 nm to 100 nm, inclusive, and the film density is set to 3.3 g/cm³ or more in the case of using MgO as the film material, the etching rates (sputtering resistant properties) of the samples T₄, T₅, and T₆ are improved in comparison with the MgO film (sample T_{1Ref.}) formed through the conventional electron beam evaporation method.

As described above, in the PDP 21 in the above-mentioned embodiment of the present invention, by appropriately setting the porosity, the minimum particle size, and the film density of an MgO film (protective film 7) to be formed on the front plate 22 thereof (more specifically, by setting the porosity in a range of from 0% or more to less than 10% in order to improve both of the sputtering resistant property (the porosity being preferably set to less than 10%) and the discharge delay time property (the porosity being preferably set to less than 13%), the minimum particle size in the grain distribution in a range of from 30 nm to 100 nm, inclusive, and the film density to 3.3 g/cm³ or more in the case of using MgO as the film material), the sputtering resistant property can be improved by shortening the discharge delay time; therefore, it becomes possible to achieve a PDP that is superior in the discharging properties and has a long service life.

As the dielectric protective film 7 formed on the front plate 22 of the PDP 21 in the above-mentioned embodiment of the present invention, the explanation has been given by exemplifying MgO (magnesium oxide); however, the present invention is not intended to be limited by this, and, for example, an oxide, fluoride, hydroxide, or carboxide of an alkaline earth metal, or a mixed compound of these may be used for the dielectric protective film 7.

Moreover, as the method for forming the dielectric protective film 7 formed on the front plate 22 of the PDP 21 in the above-mentioned embodiment of the present invention, the explanation has been given by exemplifying the sputtering method together with the electron beam evaporation method used for forming the comparative reference sample; however, the present invention is not intended to be limited by these, and in addition to the evaporation method and the sputtering method, a CVD method, a sol-gel method, or the like may be used, or two or more of these methods may be used in combination, to form the protective film.

By properly combining the arbitrary embodiments or modified examples of the aforementioned various embodiments or modified examples, the effects possessed by each of the embodiments or modified examples can be produced.

### INDUSTRIAL APPLICABILITY

According to the present invention, the plasma display panel (PDP) and the protective film to be formed on the front plate of the PDP manufactured by its manufacturing method have an excellent electron discharging property, and are superior in the sputtering resistant property; therefore, by using this protective film, it becomes possible to manufacture a PDP that is superior in the image quality with high definition, and has a long service life, and a large-size, thin flat panel display apparatus utilizing such a PDP can be applied to a large-size television receiver and a public displaying monitor.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

1-7. (canceled)

8. A plasma display panel comprising:
a first substrate having a first glass substrate on which a first electrode, a first dielectric layer, and a protective film are formed; and
a second substrate having a second glass substrate on which a second electrode, a second dielectric layer, partition walls, and phosphor layers are formed,
wherein the first substrate and the second substrate are aligned face to face with each other with discharge spaces interposed in between, the protective film has a structure in which grain-state crystals are aggregated, and on a surface of the protective film, an area occupied by voids among the crystals is set in a range greater than 0% and less than 10%, with respect to an area of the protective film.

9. The plasma display panel according to claim 8, wherein the grain-state crystals of the protective film have a minimum particle size in a range of from 30 nm to 100 nm, inclusive.

10. The plasma display panel according to claim 8, wherein the protective film is formed by at least one kind of material selected from the group consisting of an oxide, fluoride, hydroxide, and carboxide of an alkaline earth metal.

11. The plasma display panel according to claim 9, wherein the protective film is formed by at least one kind of material selected from the group consisting of an oxide, fluoride, hydroxide, and carboxide of an alkaline earth metal.

12. The plasma display panel according to claim 8, wherein the protective film is formed by a compound prepared by mixing at least two kinds of materials selected from the group consisting of an oxide, fluoride, hydroxide, and carboxide of an alkaline earth metal.

13. The plasma display panel according to claim 9, wherein the protective film is formed by a compound prepared by mixing at least two kinds of materials selected from the group consisting of an oxide, fluoride, hydroxide, and carboxide of an alkaline earth metal.

14. The plasma display panel according to claim 8, wherein the protective film is made from magnesium oxide, and the protective film has a film density of greater than 3.3 g/cm³.

15. The plasma display panel according to claim 9, wherein the protective film is made from magnesium oxide, and the protective film has a film density of greater than 3.3 g/cm³.
